(19) United States
(12) Patent Application Publication
(10) Pub. No.: US 2019/0348414 A1
(43) Pub. Date: Nov. 14, 2019

(54) SEMICONDUCTOR DEVICES

(71) Applicant: SAMSUNG ELECTRONICS CO., LTD., SUWON-SI (KR)

(72) Inventors: Seung-Soo HONG, Yeonsu-gu (KR); Bo-Ra LIM, Seoul (KR); Geum-Jung SEONG, Seoul (KR); Young-Mook OH, Hwaseong-si (KR); Jeong-Yun LEE, Hwaseong-si (KR); Ah-Reum JI, Hwaseong-si (KR)

(21) Appl. No.: 16/216,538

(22) Filed: Dec. 11, 2018

(30) Foreign Application Priority Data
May 14, 2018 (KR) 10-2018-0054878

(51) Int. Cl. H01L 27/088; H01L 21/8234; H01L 29/66

(52) U.S. Cl. CPC H01L 27/0886; H01L 29/66545; H01L 21/823481

(57) ABSTRACT

A semiconductor device has active fins defined by an isolation pattern on a substrate, each of the active fins extending in a first direction, and the active fins being spaced apart from each other in a second direction crossing the first direction, a gate electrode extending in the second direction on the active fins and the isolation pattern, and an isolation structure on a portion of the isolation pattern between the active fins neighboring with each other in the second direction. The isolation structure includes a first pattern having a first material and a second pattern having a second material different from the first material. The second pattern covers a lower surface and a lower side surface of the first pattern but not an upper side surface of the first pattern.

### PRIORITY STATEMENT

This application claims priority under 35 USC § 119 to Korean Patent Application No. 10-2018-0054878, filed on May 14, 2018 in the Korean Intellectual Property Office (KIPO), the contents of which are hereby incorporated by reference in their entirety.

### BACKGROUND

### 1. Field

The inventive concept relates to a semiconductor device such as a finFET. More particularly, the inventive concept relates to the isolation structure of a gate of a semiconductor device such as a finFET.

### 2. Description of the Related Art

In a process for forming a finFET, a dummy gate may be formed on active fins, and an isolation layer may be formed at a portion of the dummy gate between the active fins to separate the dummy gate. In a process for replacing the dummy gate with a gate of a transistor (i.e., the FET), when a distance between the active fin and the isolation layer is small, the dummy gate may not be properly removed. In this case, the gate and the active fin may not contact each other, and thus a threshold voltage distribution may occur.

### SUMMARY

According to an aspect of the inventive concept, there is provided a semiconductor including a substrate, an isolation pattern defining active fins on the substrate, each of the active fins extending longitudinally in a first direction, and the active fins being spaced in a second direction crossing the first direction, a gate electrode extending longitudinally in the second direction on the active fins and the isolation pattern, and an isolation structure on a portion of the isolation pattern interposed between neighboring ones of the active fins in the second direction. The isolation structure includes a first pattern of first material, and a second pattern of second material different from the first material. The second pattern covers the bottom surface and a lower part of a side surface of the first pattern, and the second pattern has an upper surface adjacent a boundary between the lower part of the side surface of the first pattern and an upper part of the side surface of the first pattern. Thus, the second pattern does not to cover the upper part of the side surface of the first pattern.

According to another aspect of the inventive concept, there is provided a semiconductor device including a gate electrode extending longitudinally in a direction on a substrate, and an insulating isolation structure extending through the gate electrode to separate the gate electrode into two parts in said direction. The insulating isolation structure includes an upper portion, and a lower portion having a width greater than a width of the upper portion as each taken in said direction. The lower portion of the insulating isolation structure includes an inner portion of first material and integral with the upper portion, and an outer portion of second material different from the first material and extending around the inner portion.

According to another aspect of the inventive concept, there is provided a semiconductor device including

a substrate, an isolation pattern defining active fins on the substrate, each of the active fins extending longitudinally in a first direction, and the active fins being spaced in a second direction crossing the first direction, a gate structure extending in the second direction on the active fins and the isolation pattern, a gate spacer covering each of opposite side surfaces in the first direction of the gate structure, and an isolation structure extending through the gate structure and including a second pattern and a first pattern stacked. The first and second patterns are of different materials from each other, and the second pattern of the isolation structure is spaced from the gate spacer so as to not contact the gate spacer.

### BRIEF DESCRIPTION OF THE DRAWINGS

FIGS. 1 to 22 illustrate stages of a method of manufacturing a semiconductor device in accordance with the inventive concept, wherein FIGS. 1, 3, 6, 9, 13, 16 and 18 are plan views of the device during the course of its manufacture, and FIGS. 2, 4, 10, 14, 15, 17 and 19 are cross-sectional views taken along lines A-A′ of corresponding ones of the plan views, respectively, FIGS. 5, 7, 11 and 20 are cross-sectional views taken along lines B-B′ of corresponding ones of the plan views, respectively, and FIGS. 8, 12 and 21 are cross-sectional views taken along lines C-C′ of corresponding ones of the plan views, respectively.

FIGS. 22 and 23 are cross-sectional views of examples of semiconductor devices in accordance with the inventive concept.

FIGS. 24 and 25 are cross-sectional views of examples of a semiconductor device in accordance with the inventive concept.

FIG. 26 is a cross-sectional view of a semiconductor device in accordance with the inventive concept.

FIGS. 27 to 38 illustrate stages of another example of a method of manufacturing a semiconductor device in accordance with the inventive concept, wherein FIGS. 27, 30, 33 and 35 are plan views of the device during the course of its manufacture, and FIGS. 28, 34 and 36 are cross-sectional views taken along lines A-A′ of corresponding ones of the plan views, respectively, FIGS. 29, 31 and 37 are cross-sectional views taken along lines B-B′ of corresponding ones of the plan views, respectively, and FIGS. 32 and 38 are cross-sectional views taken along lines C-C′ of corresponding ones of the plan views, respectively.

### DETIALED DESCRIPTION

Examples of semiconductor devices and methods of manufacturing semiconductor devices in accordance with the inventive concept will be described more fully hereinafter with reference to the accompanying drawings.

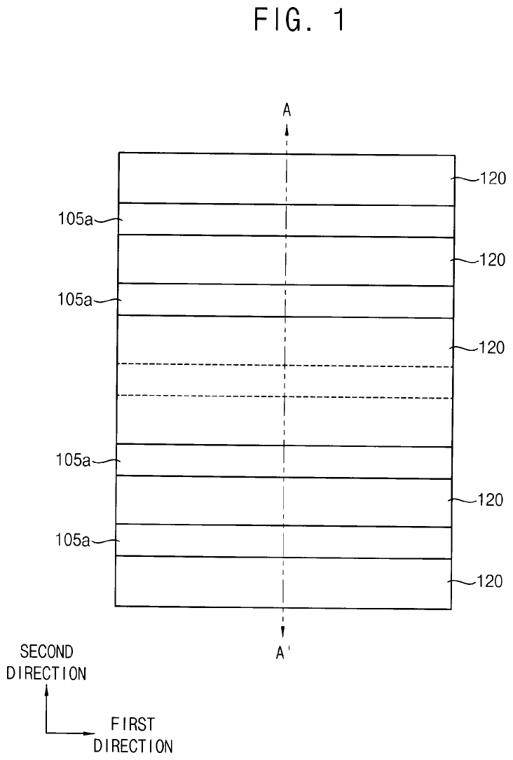

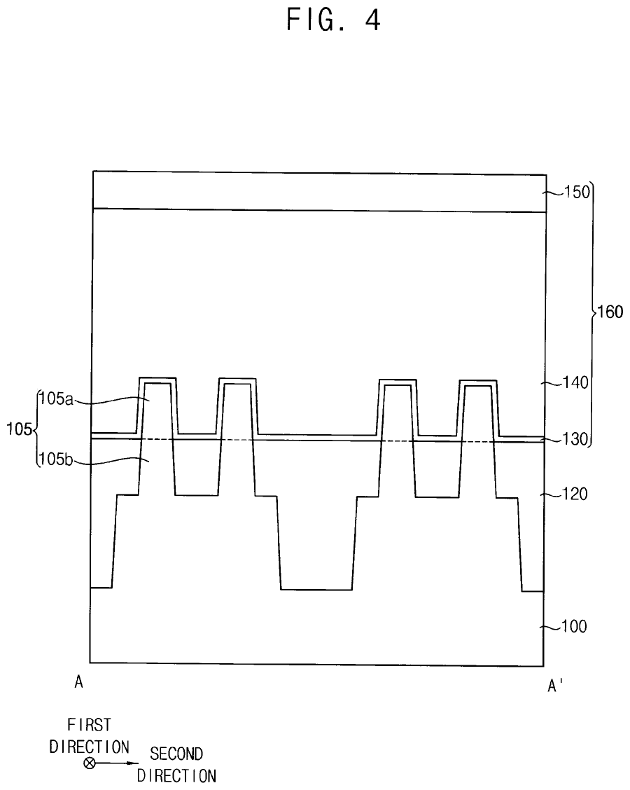

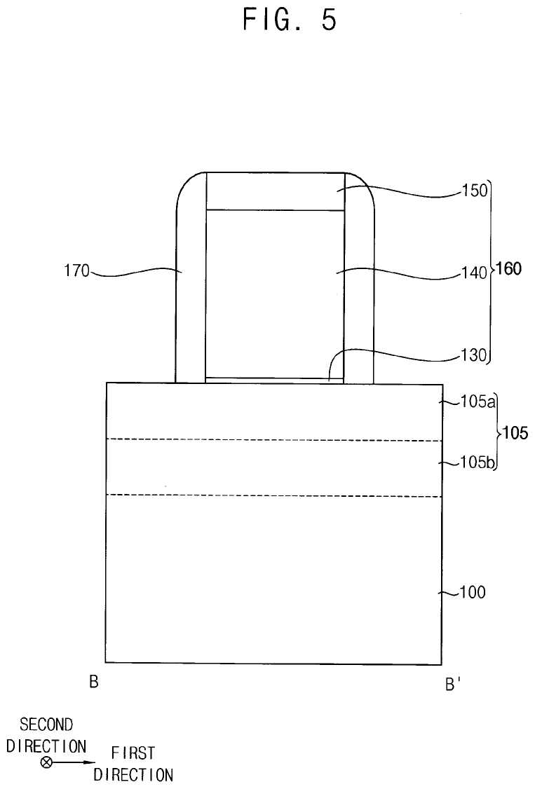

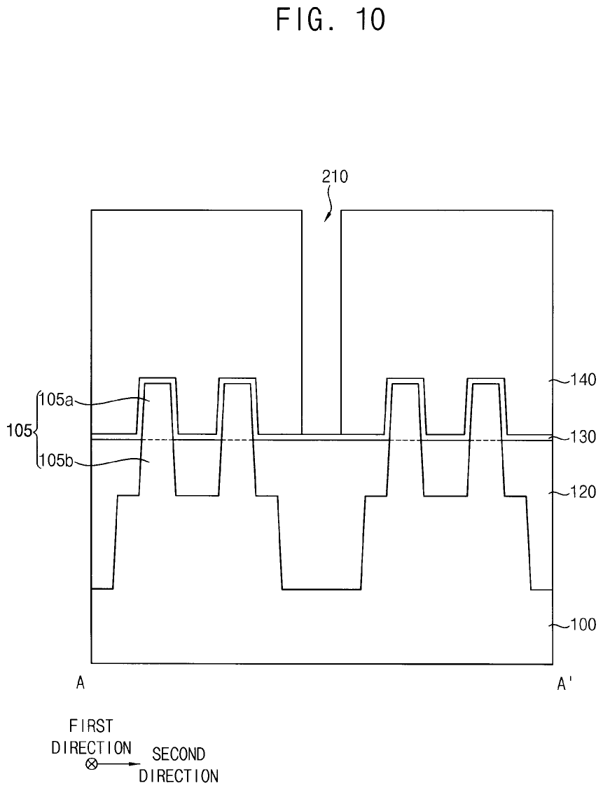

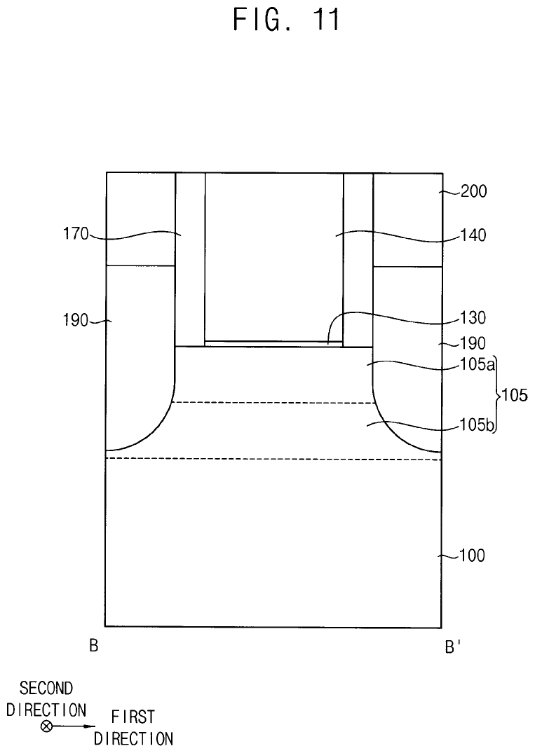

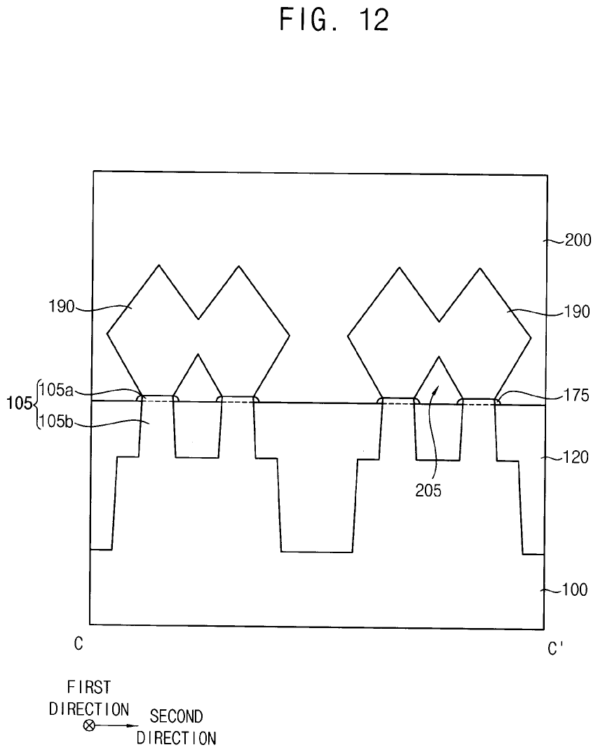

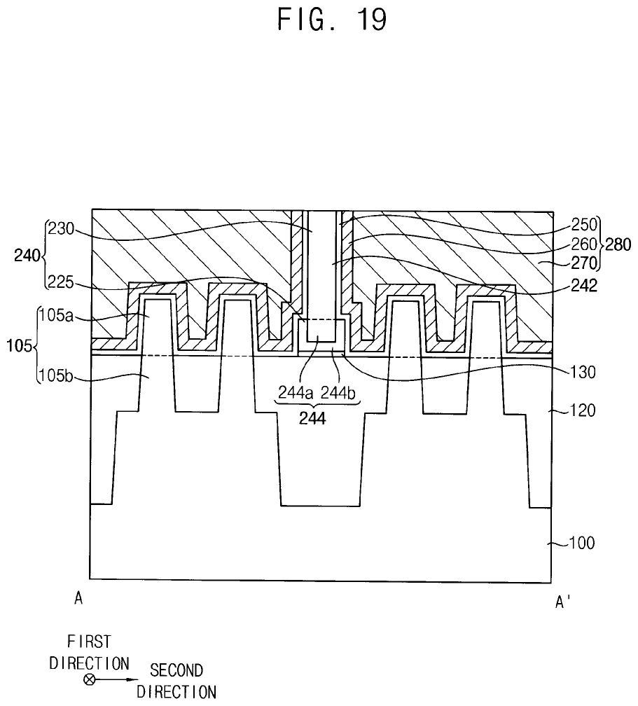

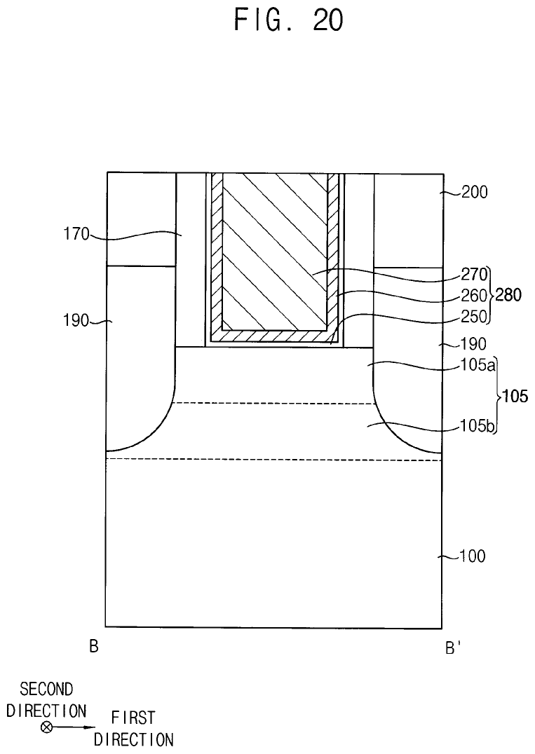

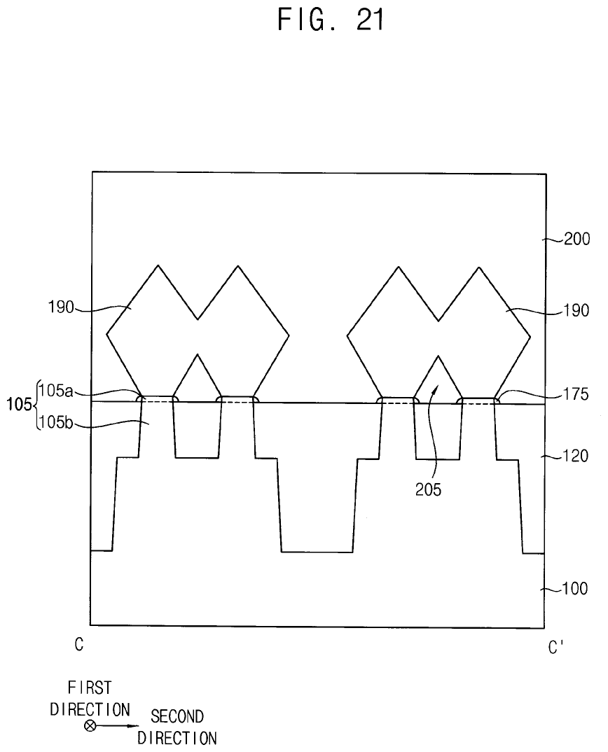

An example of a semiconductor device and a method of manufacturing a semiconductor device in accordance with the inventive concept will now be described in detail with reference to FIGS. 1 to 21.

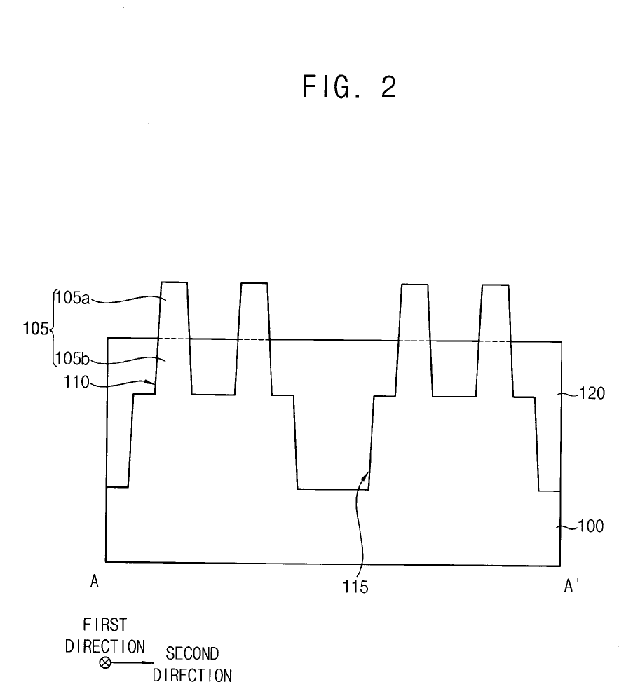

Referring first to FIGS. 1 and 2, an upper portion of a substrate 100 may be partially etched to form a first recess 110, and an active fin 105 protruding from the substrate 100 may be formed.

The substrate 100 may include silicon, germanium, silicon-germanium or a compound, e.g., GaP, GaAs, GaSb, or the like. In some examples, the substrate 100 is a silicon-on-insulator (SOI) substrate or a germanium-on-insulator (GOI) substrate.

The active fin 105 may extend longitudinally in a first direction substantially parallel to an upper surface of the substrate 100, and a plurality of the active fins 105 may be formed as spaced in a second direction substantially parallel to the upper surface of the substrate 100 and crossing the first direction. The first and second direction may cross each other at a right angle.

An etching mask (not shown) may be formed to cover one or some of the active fins 105 and expose another or other ones thereof, and the exposed ones of the active fins 105 and portions of the substrate 100 thereunder may be etched by using the etching mask to form a second recess 115.

After removing the etching mask, an isolation layer covering the active fins 105 may be formed on the substrate 100, an upper portion of the isolation layer may be removed to leave a remnant of the isolation layer covering a lower side surface of each of the active fins 105.

The active fin 105 may include a lower active pattern 105b of which a side surface is covered by the isolation pattern 120, and an upper active pattern 105a protruding from an upper surface of the isolation pattern 120.

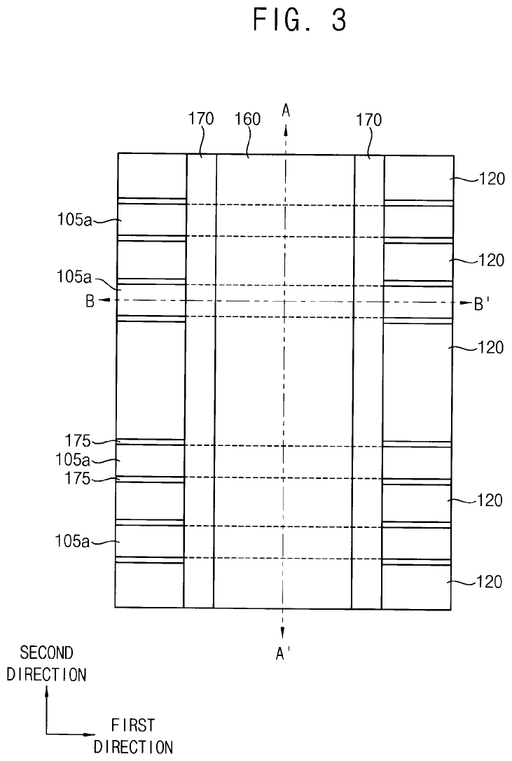

Referring to FIGS. 3 to 5, a dummy gate structure 160 may be formed on the active fins 105 and the isolation pattern 120.

For example, a dummy gate insulation layer, a dummy gate electrode layer and a dummy gate mask layer may be sequentially formed on the active fins 105 of the substrate 100 and the isolation pattern 120, the dummy gate mask layer may be patterned to form a dummy gate mask 150, and the dummy gate electrode layer and the dummy gate insulation layer may be sequentially etched using the dummy gate mask 150 as an etching mask to form the dummy gate structure 160.

Accordingly, the dummy gate structure 160 including a dummy gate insulation pattern 130, a dummy gate electrode 140 and the dummy gate mask 150 sequentially stacked may be formed on the substrate 100.

The dummy gate insulation layer may include an oxide, e.g., silicon oxide, the dummy gate electrode layer may include polysilicon, for example, and the dummy gate mask layer may include a nitride, e.g., silicon nitride.

The dummy gate insulation layer, the dummy gate electrode layer and the dummy gate mask layer may be formed by a chemical vapor deposition (CVD) process, an atomic layer deposition (ALD) process, or a like process.

The dummy gate structure 160 may extend longitudinally in the second direction, and a plurality of the dummy gate structures 160 ay be formed as spaced from each other in the first direction.

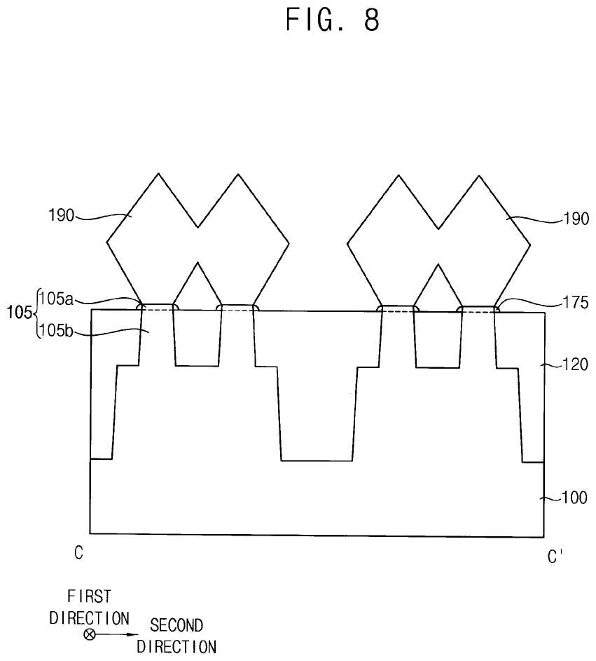

After a spacer layer is formed on the active fin 105 of the substrate 100 and the isolation pattern 120 to cover the dummy gate structure 160, the spacer layer may be anisotropically etched to form a gate spacer 170 on each of opposite side surfaces of the dummy gate structure 160 in the first direction. A fin spacer 175 (see FIG. 8) may be formed on each of opposite side surfaces of the upper active pattern 105a in the second direction.

The spacer layer may include an oxide, e.g., silicon oxide. In one example, the spacer layer has a stacked structure including a nitride layer and an oxide layer sequentially stacked.

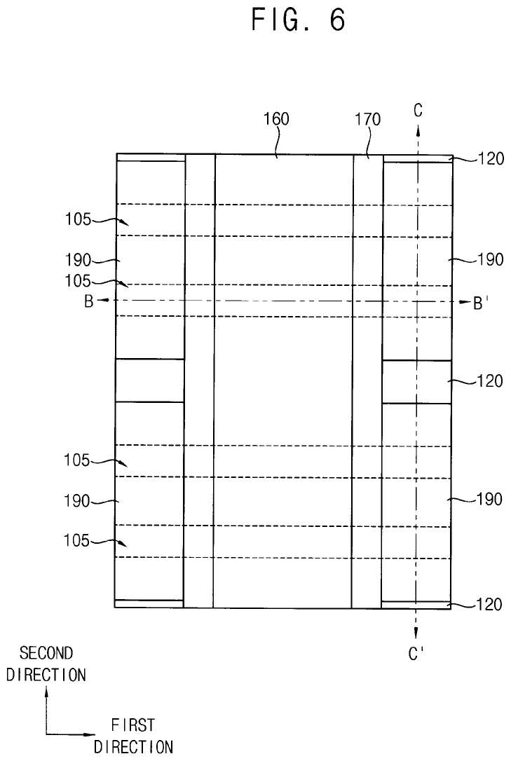

Referring to FIGS. 6 to 8, an upper portion of the active fin 105 adjacent to the gate spacer 170 may be etched to form a third recess 180.

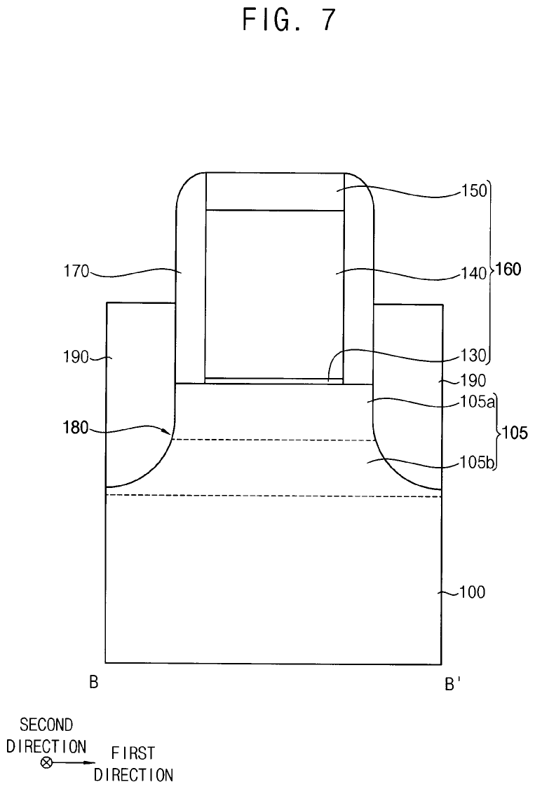

FIG. 7 shows that a portion of the upper active pattern 105a of the active fin 105 is etched to form the third recess 180, and a lower surface of the third recess 180 is higher than an upper surface of the lower active pattern 105b; however, the inventive concept is not limited thereto. For example, not only the upper active pattern 105a but also a portion of the lower active pattern 105b may be etched to form the third recess 180, and thus the bottom of the third recess 180 may be lower than an upper surface of a portion of the lower active pattern 105b.

When the third recess 180 is formed, the fin spacer 175 on each of opposite side surfaces in the second direction of the upper active pattern 105a may be completely removed or partially removed so that a portion of the fin spacer 175 may remain.

A process for forming the third recess 180 may be performed in-situ with a process for forming the gate spacer 170 and the fin spacer 175.

A source/drain layer 190 may be formed to fill the third recess 180.

A selective epitaxial growth (SEG) process using an upper surface of the active fin 105 exposed by the third recess 180 as a seed may be performed to form the source/drain layer 190.

In such an example, the SEG process may be performed using a silicon source gas, a germanium source gas, an etching gas and a carrier gas, and thus a single crystalline silicon-germanium layer may be formed to serve as the source/drain layer 190. Additionally, the SEG process may be performed using a p-type impurity source gas, and thus a single crystalline silicon-germanium layer doped with p-type impurities may be formed to serve as the source/drain layer 190.

Alternatively, the SEG process may be performed using a silicon source gas, a carbon source gas, an etching gas and a carrier gas, and thus a single crystalline silicon carbide layer may be formed as the source/drain layer 190. Additionally, the SEG process may be performed using an n-type impurity source gas, and thus a single crystalline silicon carbide layer doped with n-type impurities may be formed to serve as the source/drain layer 190. Alternatively, the SEG process may be performed using a silicon source gas, an etching gas and a carrier gas, and thus a single crystalline silicon layer may be formed as the source/drain layer 190. In this case, a single crystalline silicon layer doped with n-type impurities may be formed using an n-type impurity source gas together with the above-mentioned gases.

The source/drain layer 190 may grow not only in a vertical direction but also in a horizontal direction to fill the third recess 180, and may contact a side surface of the gate spacer 170. In example embodiments, the source/drain layer 190 may have a cross-section taken along the second direction having a pentagon-like shape.

In some examples, neighboring ones of the active fins 105 disposed in the second direction are close to each other, so much so that the source/drain layers 190 growing on the neighboring ones of the active fins 105, respectively, are merged with each other. FIG. 8 shows that two source/drain layers 190 grown on neighboring two active fins 105, respectively, are merged with each other; however, the inventive concept is not limited thereto. Thus, for example, more than two source/drain layers 190 may be merged with each other.

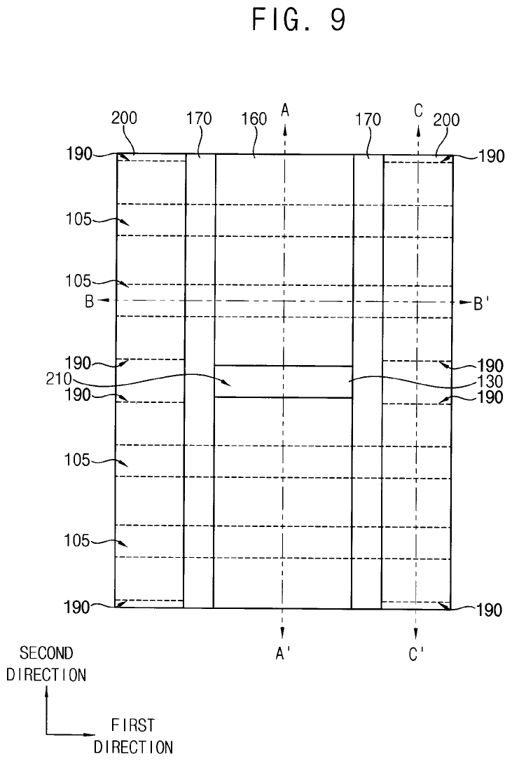

Referring to FIGS. 9 to 12, an insulating interlayer 200 covering the dummy gate structure 160, the gate spacer 170, the fin spacer 175 and the source/drain layer 190 may be formed on the active fin 105 and the isolation pattern 120 to a sufficient height, and the insulating interlayer 200 may be planarized until an upper surface of the dummy gate electrode 140 of the dummy gate structure 160 is exposed. In the planarization process, the dummy gate mask 150 and an upper portion of the gate spacer 170 may be removed.

A space between the merged source/drain layer 190 and the isolation pattern 120 may not be completely filled with the insulating interlayer 200, and thus an air gap 205 may be formed therein.

The insulating interlayer 200 may include a silicon oxide, e.g., tonen silazene (TOSZ). The planarization process may be performed by a chemical mechanical polishing (CMP) process and/or an etch back process.

A portion of the exposed dummy gate electrode 140 may be removed by an etching process using an etching mask (not shown) to form a first opening 210 exposing the dummy gate insulation pattern 130. In some examples, in the etching process, the dummy gate insulation pattern 130 is also removed to expose the isolation pattern 120.

An upper surface of a portion of the dummy gate insulation pattern 130 on the isolation pattern 120 between the neighboring active fins 105 in the second direction may be exposed by the first opening 210.

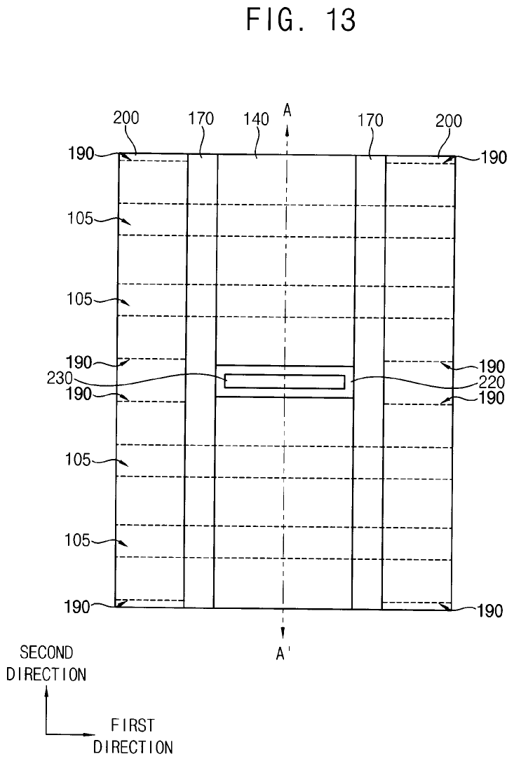

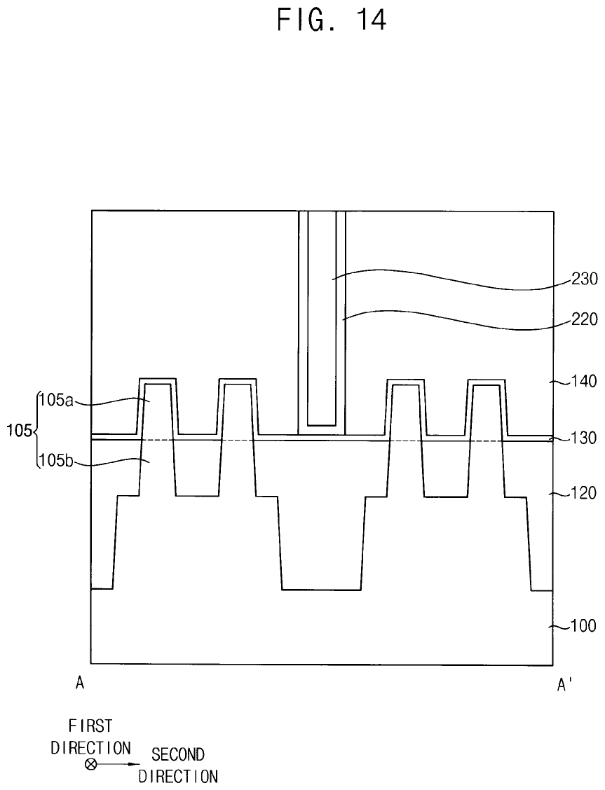

Referring to FIGS. 13 and 14, after the etching mask has been removed, a second preliminary pattern 220 may be formed along the bottom and sides of the first opening 210, and a first pattern 230 may be formed on the second preliminary pattern 220 to fill a remaining portion of the first opening 210.

Specifically, a second layer may be formed along the bottom and sides of the first opening 210, the dummy gate electrode 140, the gate spacer 170 and the insulating interlayer 200, a first layer may be formed on the second layer to fill the remaining portion of the first opening 210, and the first and second layer may be planarized until the upper surface of the dummy gate electrode 140 is exposed to form the first pattern 230 and the second preliminary pattern 220.

The first pattern 230 and the second preliminary pattern 220 are of materials different in kind from each other. For example, the first pattern 230 may be a pattern of material having a low dielectric constant, e.g., silicon carbonitride (SiCN) or silicon oxycarbonitride (SiOCN), and the second preliminary pattern 220 may be a pattern of silicon nitride (SiNₓ) or silicon oxide (SiO₂). Alternatively, the first pattern 230 may be a pattern of silicon nitride (SiNₓ) and the second preliminary pattern 220 may be a pattern of silicon oxide (SiO₂). Here, the term “materials that are ‘different’ from each other” refers to differences in composition which cause the materials to have a significant etch selectivity with respect to each other.

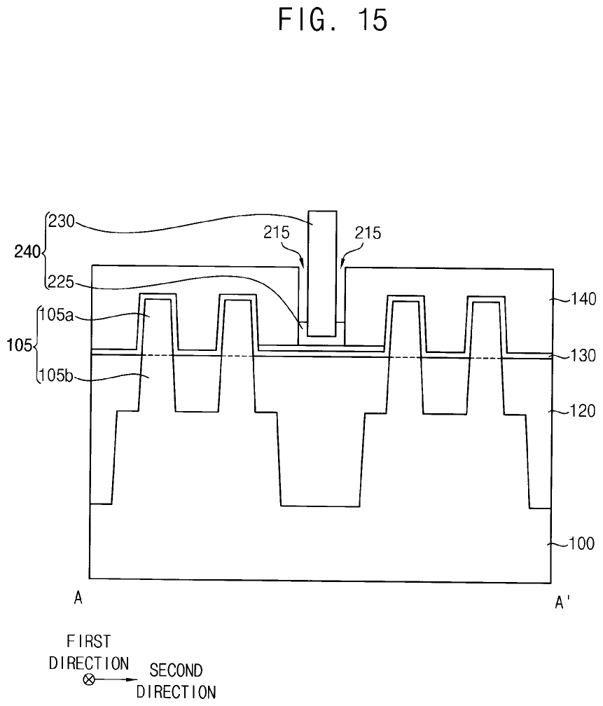

Referring to FIG. 15, an upper portion of the dummy gate electrode 140 may be removed to expose an upper portion of the second preliminary pattern 220, and the exposed upper portion of the second preliminary pattern 220 may be partially removed to form a second pattern 225.

The upper portion of the dummy gate electrode 140 may be removed by a dry etching process; however, the inventive concept is not limited thereto. The exposed upper portion of the second preliminary pattern 220 may be removed by a wet etching process; however, the inventive concept is not limited thereto.

Not only the exposed upper portion of the second preliminary pattern 220, but also a portion thereof under the remaining dummy gate electrode 140 may be removed, and an upper surface of the second pattern 225 may be substantially coplanar with or situated at a level lower than that of a top surface of each of the active fins 105. Accordingly, a gap 215 may be formed between a portion of the dummy gate electrode 140 adjacent to the first pattern 230 and a side surface of the first pattern 230. The first pattern 230 and the second preliminary pattern 220 may include materials having a high etching selectivity to each other, and thus the first pattern 230 will not be removed in a process for removing the second preliminary pattern 220.

The sequentially stacked second pattern 225 and the first pattern 230 may be referred to collectively hereinafter as isolation structure 240 or an insulating isolation structure 240.

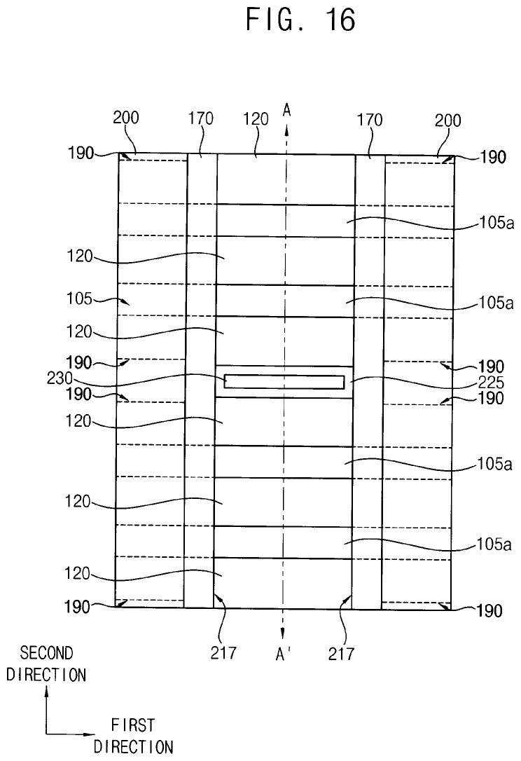

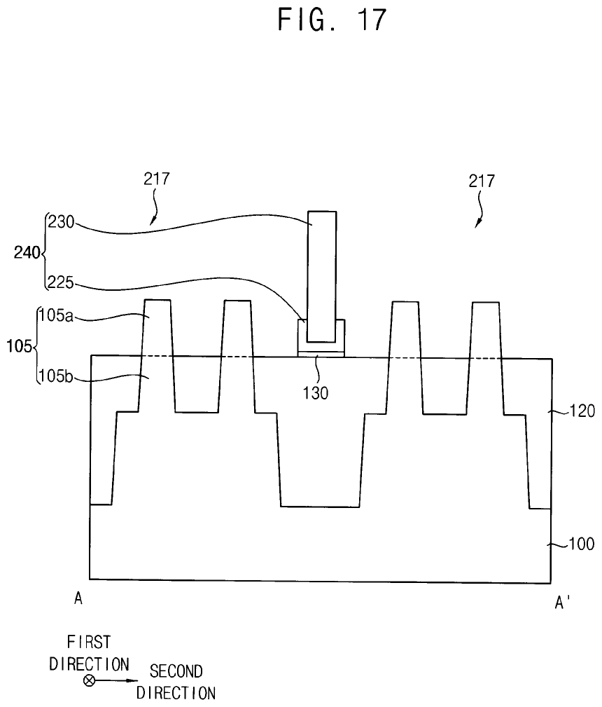

Referring to FIGS. 16 and 17, an etching process may be performed to remove the remaining dummy gate electrode 140 and a portion of the dummy gate insulation pattern 130 thereunder, so that a second opening 217 may be formed to expose the active fins 105 and the isolation pattern 120.

The etching process may be performed by a wet etching process; however, the inventive concept is not limited thereto. In the etching process, the gap 215 may exist between the dummy gate electrode 140 and the first pattern 230 of the isolation structure 240. Thus, an etchant or an etching gas may be well provided through the gap 215, so that the dummy gate electrode 140 may be easily removed.

That is, although a distance between the isolation structure 240 and the active fin 105 adjacent thereto is small, not only the upper surface, but also at least an upper side surface of the dummy gate electrode 140 may be exposed by the gap 215, and thus a lower portion of the dummy gate electrode 140 and the portion of the dummy gate insulation pattern 130 thereunder may be well removed through the etching process. As a result, the active fins 105 may be fully exposed by the etching process.

A portion of the dummy gate insulation pattern 130 may be left under the isolation structure, and thus the dummy gate insulation pattern 130 may remain between the isolation pattern 120 and the isolation structure 240.

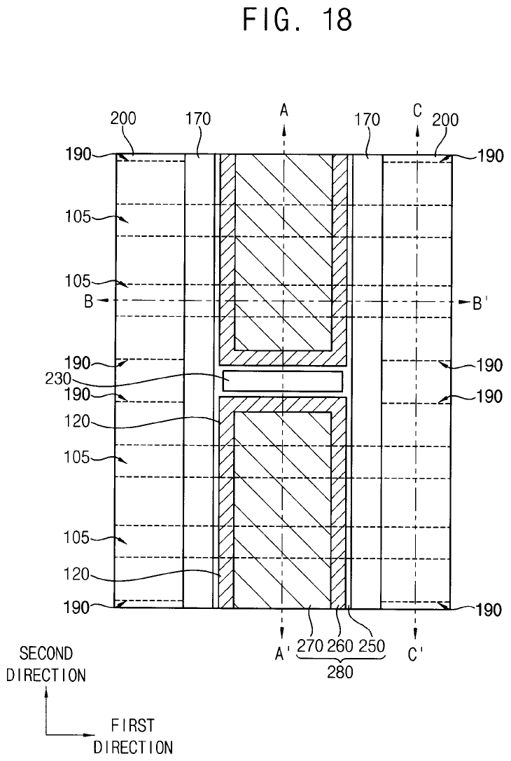

Referring to FIGS. 18 to 21, a gate structure 280 may be formed to fill the second opening 217.

For example, a gate insulation layer may be formed on the active fin 105 exposed by the second opening 217, the isolation pattern 120 and the isolation structure 240, the gate spacer 170, and the insulating interlayer 200, a work function control layer may be formed on the gate insulation layer, and a gate conductive layer may be formed on the work function control layer to fill a remaining portion of the second opening 217.

The gate conductive layer, the work function control layer and the gate insulation layer may be planarized until an upper surface of the insulating interlayer 200 is exposed. Thus, a gate insulation pattern 250 may be formed on an upper surface of the active fin 105, an upper surface of the isolation pattern 120, a side surface of the isolation structure 240, and an inner side surface of the gate spacer 170, a work function control pattern 260 may be formed on the gate insulation pattern 250, and a gate conductive pattern 270 may be formed on the work function control pattern 260 to fill the remaining portion of the second opening 217.

The work function control pattern 260 and the gate conductive pattern 270 sequentially stacked may form a gate electrode, and the gate electrode and the gate insulation pattern 250 covering a lower surface and a side surface of the gate electrode may form a gate structure 280. The gate structure 280 together with the neighboring source/drain layer 190 in the first direction may form a transistor. The transistor may be a PMOS transistor or an NMOS transistor depending on the conductivity type of the source/drain layer 190.

The gate insulation pattern 250 may include a metal oxide having a high dielectric constant, e.g., hafnium oxide (HfO₂), tantalum oxide (Ta₂O₅), zirconium oxide (ZrO₂), or the like, the work function control pattern 260 may include a metal nitride or a metal alloy, e.g., titanium nitride (TiN), titanium aluminum (TiAl), titanium aluminum nitride (TiAlN), tantalum nitride (TaN), tantalum aluminum nitride (TaAlN), or the like, and the gate conductive pattern 270 may include a metal having a low electrical resistance, e.g., aluminum, copper, tantalum, or the like or a metal nitride thereof.

Contact plugs (not shown) and upper wirings (not shown) may be connected to the gate structure 280 and/or the source/drain layer 190 to complete the fabrication of the semiconductor device.

As described above, in the method of manufacturing the semiconductor device, the isolation structure 240 may include the first pattern 230 and the second pattern 225 covering a lower surface and a lower side surface of the first pattern 230, and thus, even if a distance between neighboring ones of the active fins 105 is small, a portion of the dummy gate electrode therebetween may be well removed. Accordingly, a contact area between the gate structure 280 replacing the dummy gate electrode 140 and the active fins 105 may be well established, and thus a threshold voltage distribution may not be high.

The semiconductor device manufactured by the above-described processes may include the isolation structure 240, which may be formed on a portion of the isolation pattern 120 between neighboring ones of the active fins 105 in the second direction, and divide the gate electrode in the second direction. The isolation structure 240 may have the first pattern 230, which may include a first material, and the second pattern 225, which may include a second material different from the first material, and cover the lower surface and lower side surface of the first pattern 230. The second pattern 225 may expose an upper side surface of the first pattern 230.

The upper surface of the second pattern 225 may be substantially coplanar with or situated at a level lower than that of the top surface of each of the active fins 105. The second pattern 225 of the isolation structure 240 may surround an entire side of a lower portion of the first pattern 230 of the isolation structure 240.

The isolation structure 240 may include an upper portion 242 having a first width, and a lower portion 244 having a second width greater than the first width and including an inner portion 244a and an outer portion 244b. The inner portion 244a of the lower portion 244 and the upper portion 242 may be of substantially the same material as each other, namely, a first material, and a first and may have the first width. The inner portion 244a of the lower portion 244 and the upper portion 242 and may be sequentially stacked, and may be integrally formed with each other. The outer portion 244b of the lower portion 244 may be of material different in kind from the first material, and may cover a side surface and a lower surface of the inner portion 244a of the lower portion 244. The outer portion 244b of the lower portion 244 may surround the side surface of the inner portion 244a of the lower portion 244.

The isolation structure 240 may extend through the gate structure 280 extending in the second direction on the active fins 105 and the isolation pattern 120, and an inner side surface of the gate spacer 170 covering each of the opposite side surfaces in the first direction of the gate structure 280 may contact the gate insulation pattern 250 of the gate structure 280. Accordingly, the isolation structure 240 or the second pattern 225 of the isolation structure 240 may not contact the gate spacer 170. That is, the gate electrode including the work function control pattern 260 and the gate conductive pattern 270 of the gate structure 280 extending in the second direction may be separated by the isolation structure 240 in the second direction. However, the gate insulation pattern 250 of the gate structure 280 may extend in the second direction to cover the side surface of the isolation structure 240 and the inner side surface of the gate spacer 170.

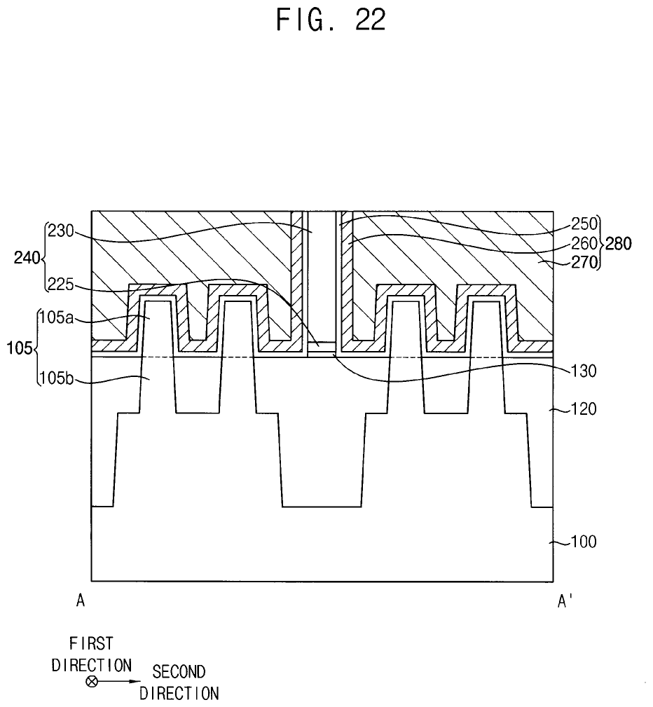

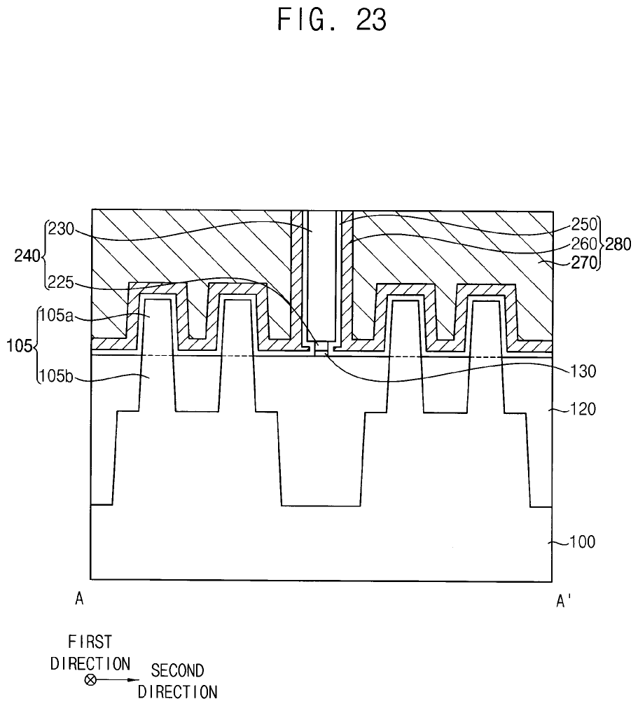

FIGS. 22 and 23 are cross-sectional views of other examples of semiconductor devices in accordance with the inventive concept. The semiconductor devices are similar to the semiconductor device described with reference to FIGS. 18 to 21 except for shapes of the isolation structures. Thus, like reference numerals refer to like elements, and detailed descriptions thereof are omitted hereinafter.

Referring to FIG. 22, the second pattern 225 of the isolation structure 240 may cover the lower surface of the first pattern 230, and may not cover the lower side surface of the first pattern 230. Accordingly, the dummy gate insulation pattern 130, the second pattern 225 and the first pattern 230 may be sequentially stacked on the isolation pattern 120 between the active fins 105, and may have substantially the same widths as each other.

In the process shown in and described with reference to FIG. 15, a portion of the second preliminary pattern 220, covering the lower surface and a side surface of the first pattern 230, on the side surface of the first pattern 230 is entirely removed to form the isolation structure 240 illustrated in FIG. 22. That is, as long as the upper surface of the second pattern 225 of the isolation structure 240 is formed to be substantially coplanar with or at a level lower than that of the upper surface of the active fins 105, even if the distance between the active fins 105 is small, a removal process of the dummy gate electrode 140 may be well performed, so that the isolation structure 240 may have the shape illustrated in FIG. 22.

Referring to FIG. 23, the second pattern 225 of the isolation structure 240 does not entirely cover the lower surface of the first pattern 230 but, for example, covers only a central lower surface of the first pattern 230. That is, in an example of a semiconductor device according to the inventive concept, only the gate electrode of the gate structure 280 extending in the second direction is divided by the isolation structure 240, i.e., the second pattern 225 of the isolation structure 240 does not necessarily cover the entire lower surface of the first pattern 230 according to the inventive concept. In this case, the second pattern 225 may have a width smaller than that of the first pattern 230.

However, the width of the second pattern 225 of the isolation structure 240 may not be so small that the isolation of the gate electrode in the second direction is incomplete.

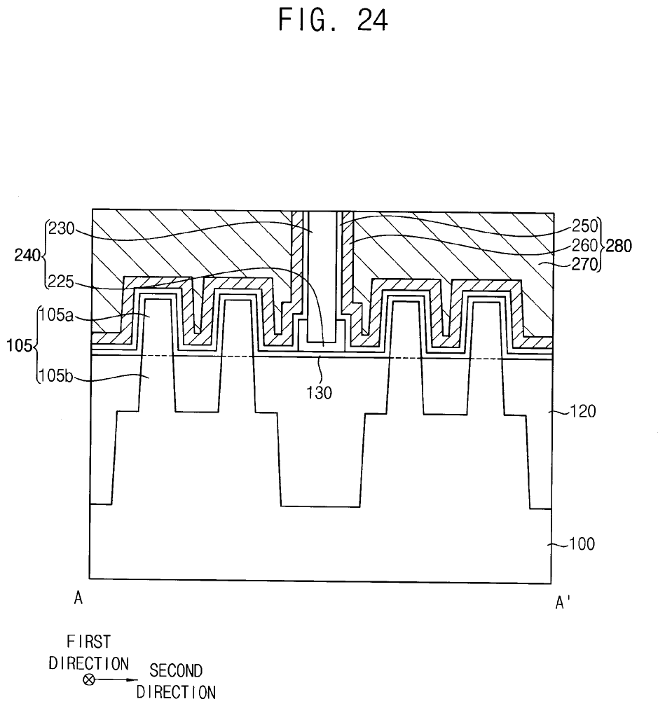

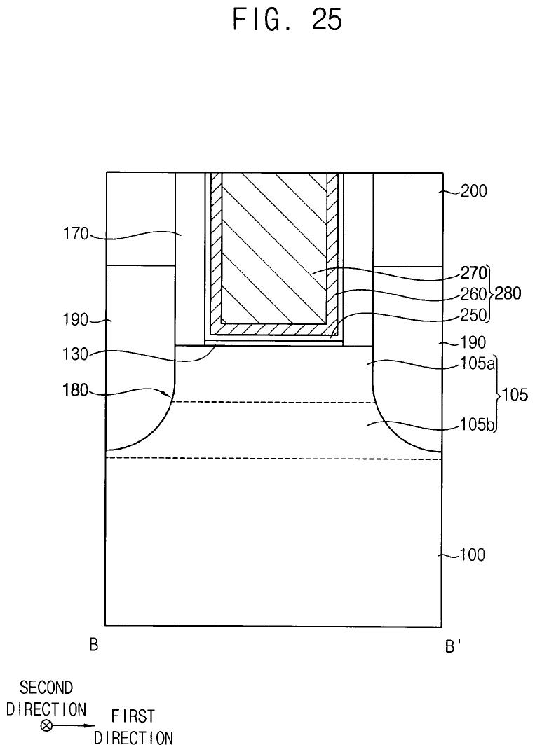

FIGS. 24 and 25 are cross-sectional views illustrating yet another example of a semiconductor device in accordance with the inventive concept. The semiconductor device is similar to the semiconductor device described with reference to FIGS. 18 to 21 except for a shape of the dummy gate insulation pattern. Thus, like reference numerals refer to like elements, and detailed descriptions thereof are omitted herein.

Referring to FIGS. 24 and 25, the dummy gate insulation pattern 130 of the semiconductor device is formed not only under the isolation structure 240, but also on the upper surfaces of the active fins 105 and the upper surface of the isolation pattern 120.

The dummy gate insulation pattern 130 under the dummy gate electrode 140 is not removed when the dummy gate electrode 140 is removed in the process described with reference to FIGS. 16 and 17. Accordingly, the dummy gate insulation pattern 130 may be interposed between the active fins 105 and the isolation pattern 120 and the gate structure 280.

The semiconductor device illustrated in FIGS. 24 and 25 may be formed on a region where a relatively high voltage is applied when compared to the semiconductor device illustrated in FIGS. 15 to 21. For example, the semiconductor device illustrated in FIGS. 18 to 21 may be formed on a cell region of memory devices, and the semiconductor device illustrated in FIGS. 24 and 25 may be formed on a peripheral circuit region of the memory devices.

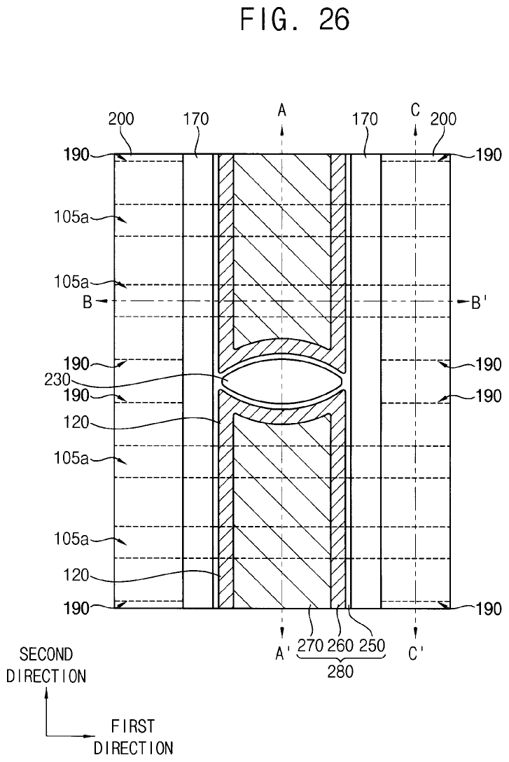

FIG. 26 is a cross-sectional view illustrating still another example of a semiconductor device in accordance with the inventive concept. The semiconductor device is similar to the semiconductor device described with reference to FIGS. 18 to 21 except for a shape of the isolation structure. Thus, like reference numerals refer to like elements, and detailed descriptions thereof are omitted herein.

Referring to FIG. 26, the first pattern 230 of the isolation structure 240 has an elliptical shape in a plan view.

The first opening 210 may have an elliptical shape because of the way etching gas inflows in the process shown and described with reference to FIGS. 9 to 12. That is, the first opening 210 would have a rectangular shape in a plan view if the same amount of the etching gas impinged portions of an area of the interlayer insulating layer 200 exposed by an etching mask. However, the first opening 210 tends to have a central convex portion, e.g., an elliptical shape or a substantially circular shape in a plan view, because more of the etching gas tends to impinge a central portion of the exposed area than opposite sides or corners of the exposed region. Accordingly, the isolation structure 240 or the first pattern 230 of the isolation structure 240 in the first opening 210 may have an elliptical or substantially circular horizontal cross-sectional shape. Here the term “substantially circular” refers to a closed rounded shape in which the radii of curvature are substantially the same or vary only slightly.

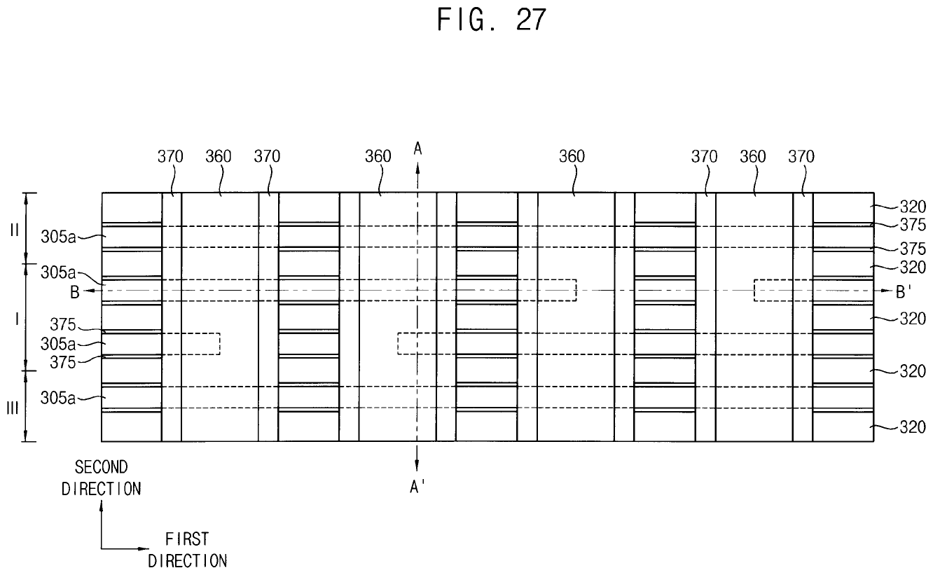

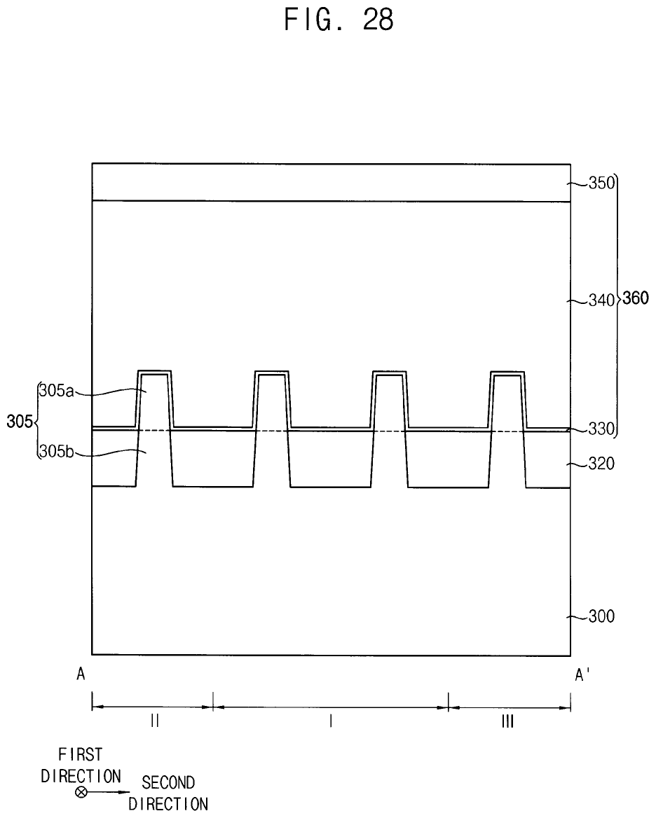

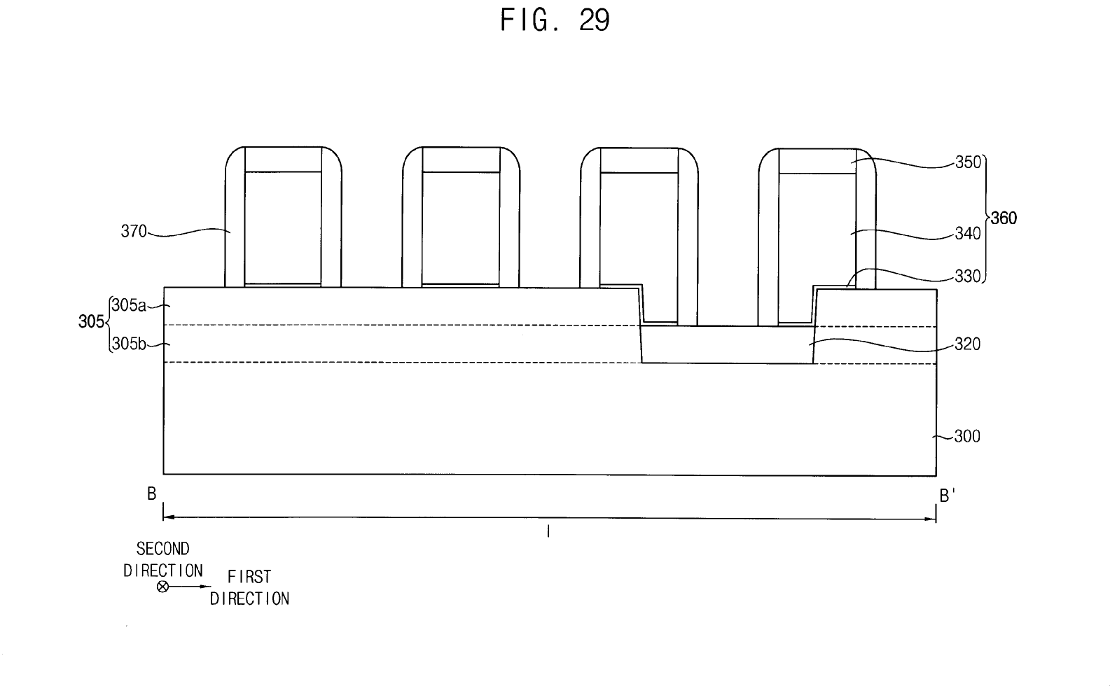

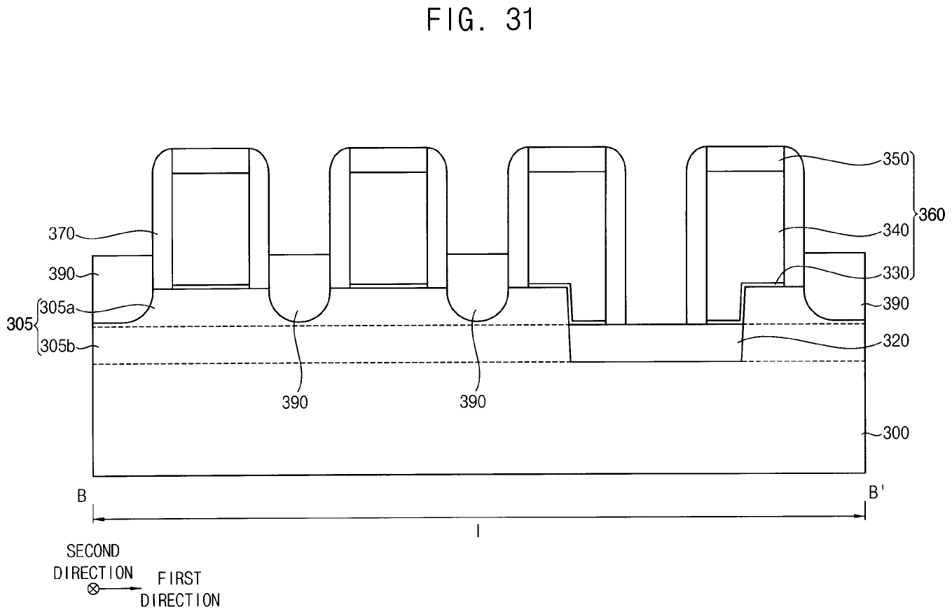

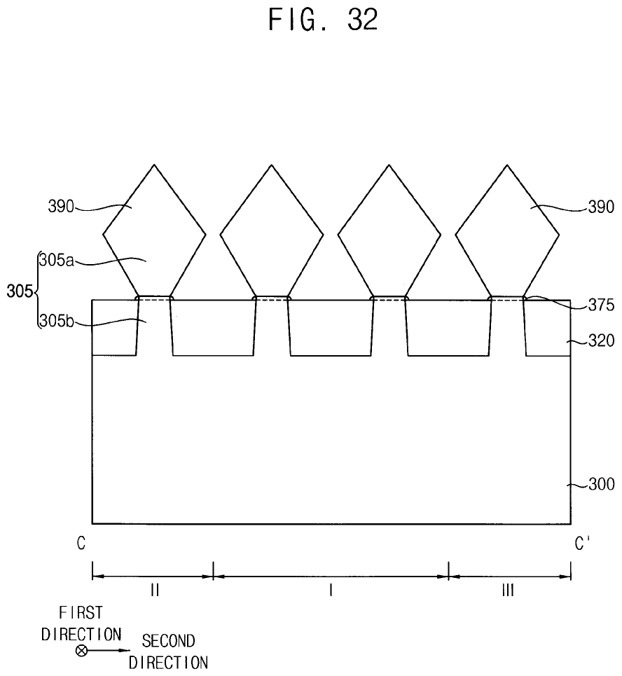

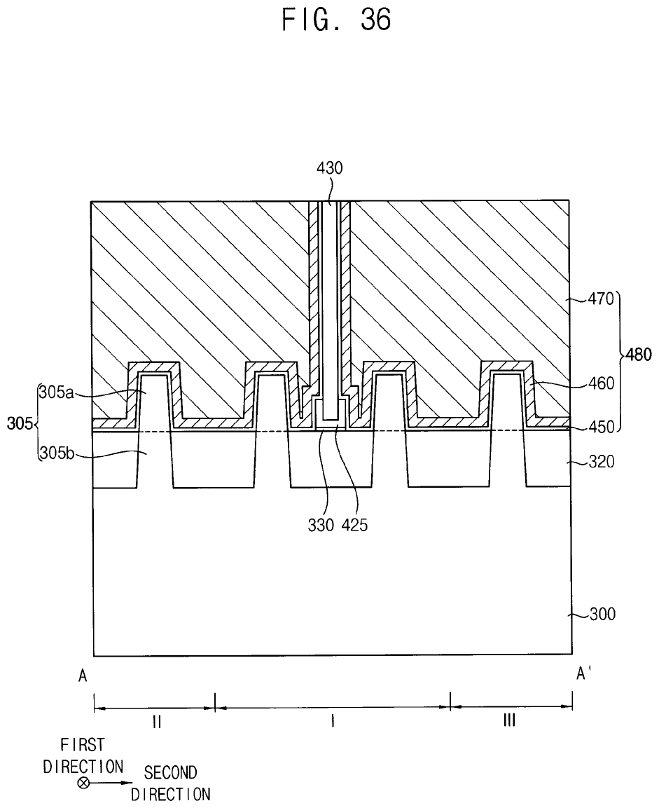

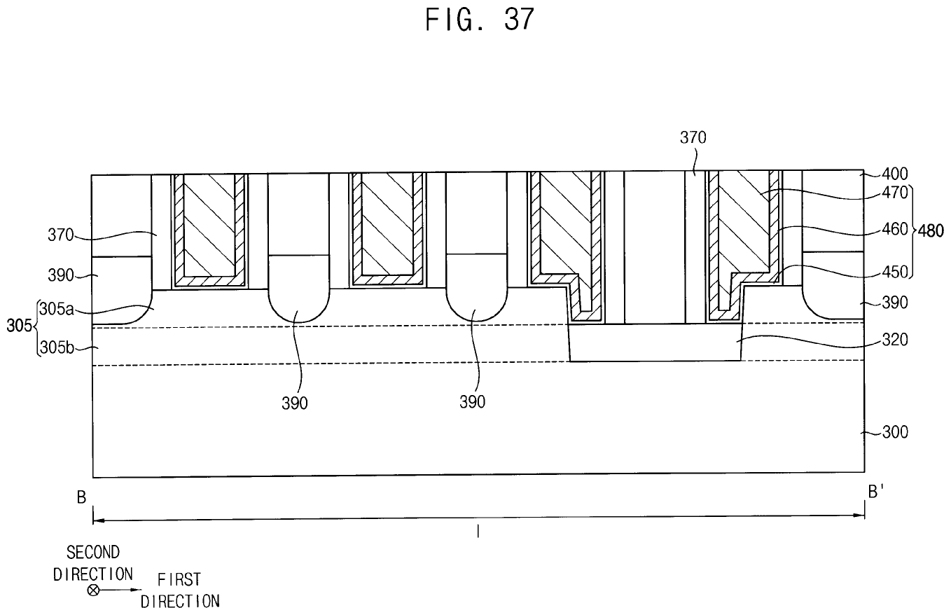

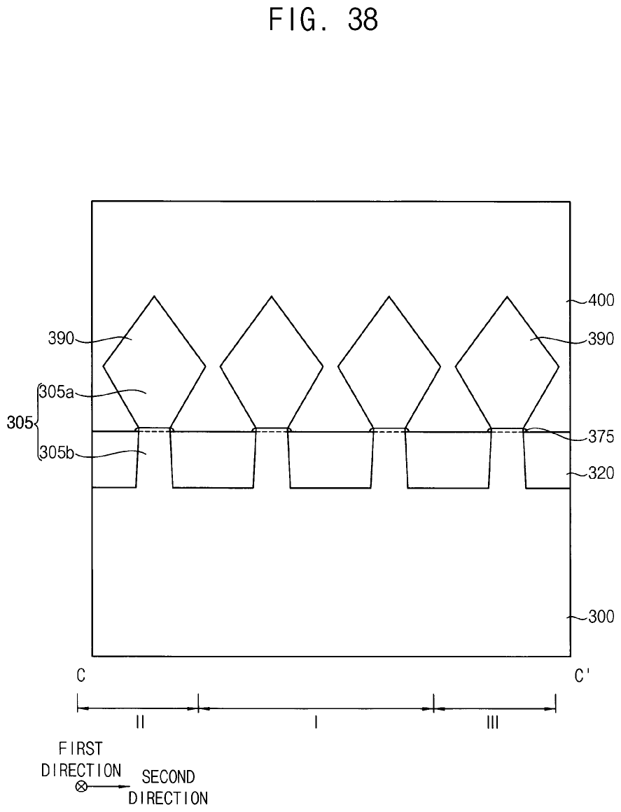

FIGS. 27 to 38 illustrate stages of another example of a method of manufacturing a semiconductor device in accordance with the inventive concept.

This example is an application of the inventive concept to a method of manufacturing an SRAM device, and may include processes similar to processes described with reference to FIGS. 1 to 21. Thus, detailed descriptions of the similar processes may be omitted or only described briefly hereinafter.

Referring to FIGS. 27 to 29, processes similar to the processes described with reference to FIGS. 1 to 5 may be performed.

In particular, an upper portion of a substrate 300 may be partially etched to form active fins 305 each of which may extend longitudinally in a first direction, an isolation pattern 320 may be formed to cover a side surface of a lower active pattern 305b of each of the active fins 305 and to expose an upper active pattern 305a of each of the active fins 305, and a dummy gate structure 360 extending longitudinally in a second direction crossing the first direction may be formed on the active fins 305 and the isolation pattern 320.

The substrate 300 may include first to third regions I, II and III. The first region I may be a PMOS region in which PMOS transistors are formed, and the second and third regions II and III may be an NMOS region in which NMOS transistors are formed at opposite sides of the first region I, respectively, in the second direction.

The active fins 305 may be formed in rows spaced in the second direction. On the other hand, respective ones of the active fins 305 may be separated from each other in the first direction in at least one of the rows. For example, the first region I of the substrate 300 may have: one or more rows each of a plurality of the active fins 305 spaced from each other in the direction (first direction) of the row.

A plurality of the dummy gate structures 360 may be formed in the first direction, and each of the dummy gate structures 360 may include a dummy gate insulation pattern 330, a dummy gate electrode 340 and a dummy gate mask 350 sequentially stacked.

A gate spacer 370 may be formed on each of opposite side surfaces of the dummy gate structure 360 in the first direction, and a fin spacer 375 may be formed on each of opposite side surfaces of the upper active pattern 305a.

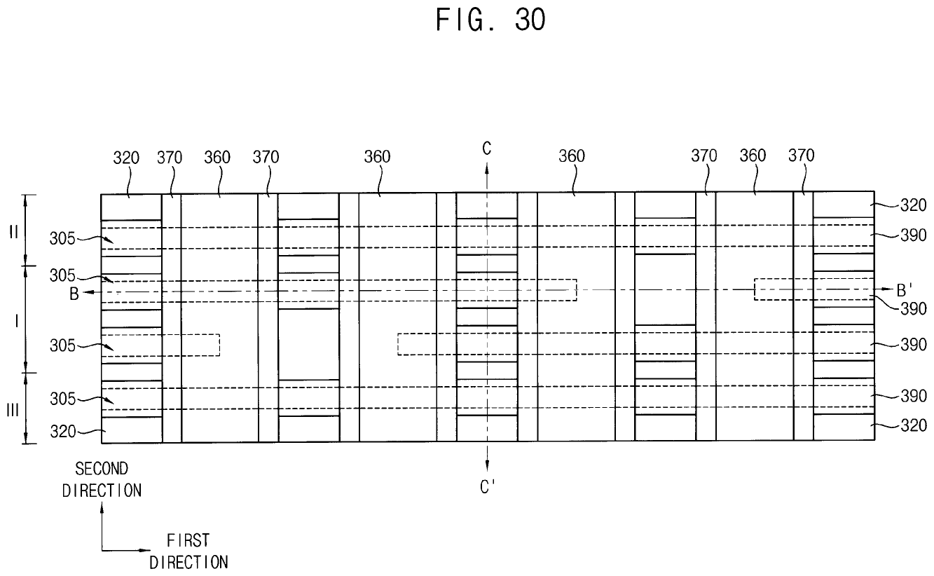

Referring to FIGS. 30 to 32, processes similar to the processes described with reference to FIGS. 6 to 8 may be performed.

Accordingly, an upper portion of the active fin 305 adjacent to the gate spacer 370 may be etched to form a third recess (not shown), and a source/drain layer 390 may be formed to fill the third recess.

In some examples, a single crystalline silicon-germanium layer doped with p-type impurities as the source/drain layer 390 is formed on the first region I of the substrate 300, and a single crystalline silicon-carbide layer doped with n-type impurities or a single crystalline silicon layer doped with n-type impurities as the source/drain layer 390 is formed on the second and third regions II and III of the substrate 300.

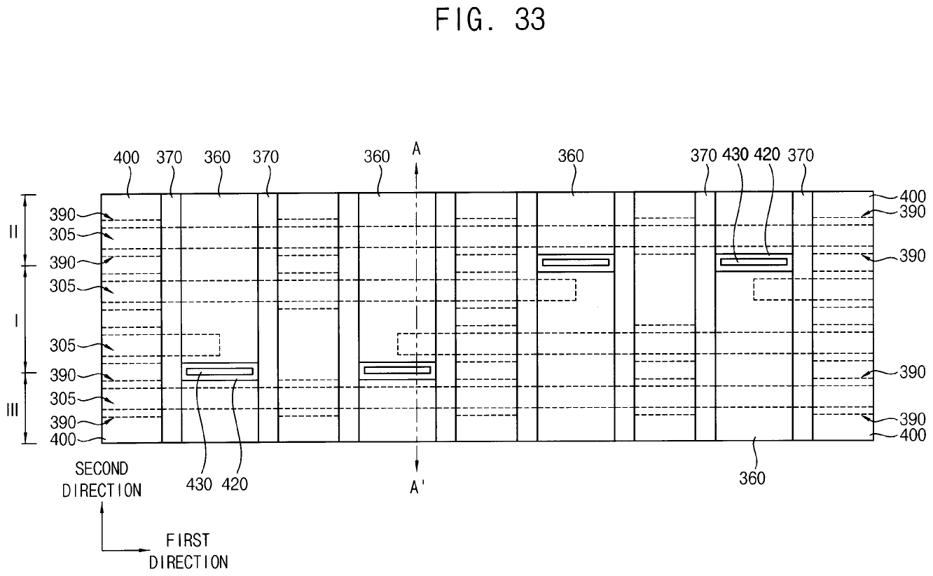

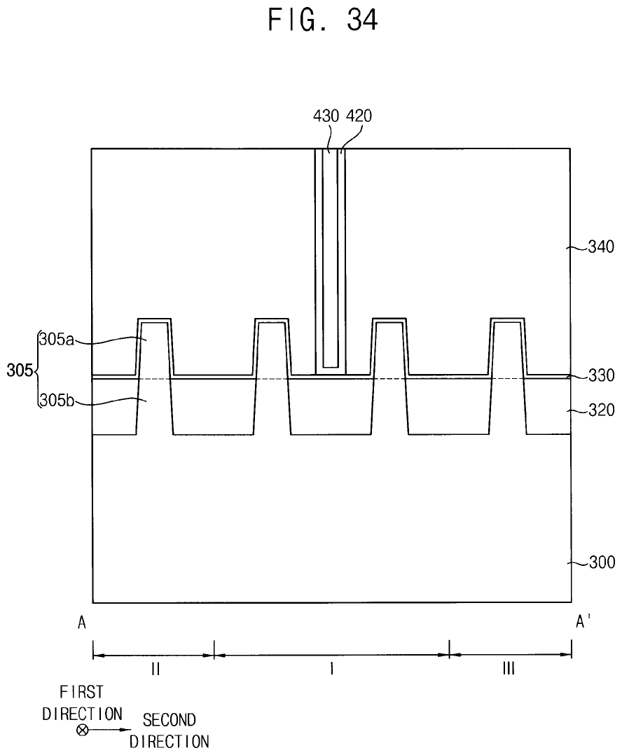

Referring to FIGS. 33 and 34, processes similar to the processes described with reference to FIGS. 9 to 14 may be performed.

Accordingly, after an insulating interlayer 400 has been formed on the active fins 305 and the isolation pattern 320 to cover the dummy gate structure 360, the gate spacer 370, the fin spacer 375 and the source/drain layer 390, the insulating interlayer 400 may be planarized until an upper surface of the dummy gate electrode 340 of the dummy gate structure 360 is exposed. During the planarization process, upper portions of the dummy gate mask 350 and the gate spacer 370 may be also removed.

A portion of the dummy gate electrode 340 extending in the second direction may be removed to form a first opening (not shown) exposing an upper surface of a portion of the dummy gate insulation pattern 330, which may be formed on the isolation pattern 320 between the active fins 305 neighboring in the second direction. A second preliminary pattern 420 may be formed along the bottom and side(s) of the first opening, and a first pattern 430 may be formed on the second preliminary pattern 420 to fill a remaining portion of the first opening.

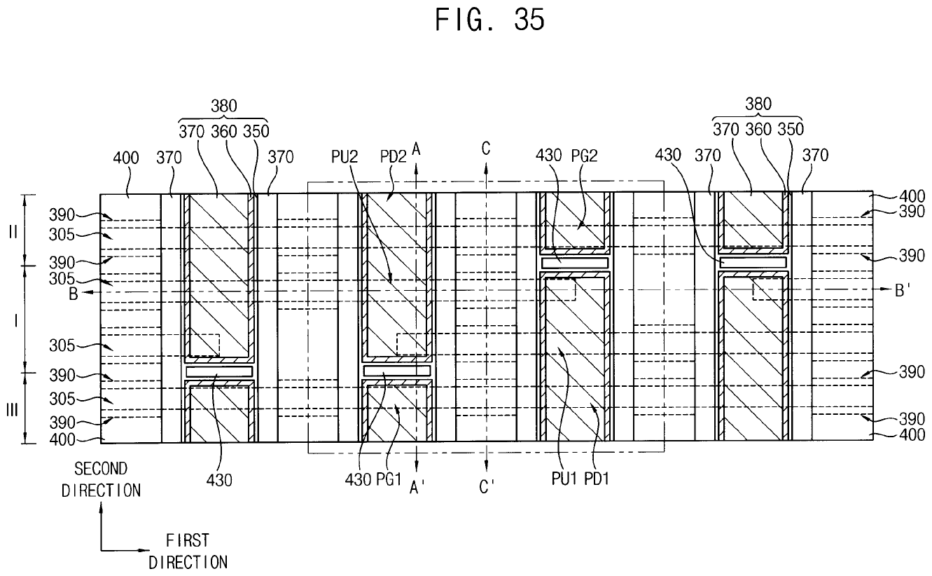

Referring to FIGS. 35 to 38, processes similar to the processes described with reference to FIGS. 15 to 21 may be performed.

After an upper portion of the dummy gate electrode 340 has been removed to expose an upper outer side surface of the second preliminary pattern. 420, the exposed portion of the second preliminary pattern 420 may be partially removed to form a second pattern 425. Thus, an isolation structure 440 including the second pattern 425 and the first pattern 430 sequentially stacked may be formed. Due to the fact that the first pattern 430 and the second preliminary pattern 420 are of respective materials having a high etching selectivity with respect to each other, hardly any of the first pattern 430 is removed when the second preliminary pattern 420 is removed.

A remaining portion of the dummy gate electrode 340 and a portion of the dummy gate insulation pattern 330 thereunder may be removed to form a second opening (not shown) exposing the active fins 305 and the isolation pattern 320. Due to a gap (not shown) existing between the dummy gate electrode 340 and the first pattern 430 of the isolation structure 440, the dummy gate electrode 340 may be well removed, so that the active fins 305 may be fully exposed.

A gate insulation pattern 450 may be formed along the bottom and side(s) of the second opening, a work function control pattern 460 may be formed on the gate insulation pattern 450, and a gate conductive pattern 470 may be formed on the work function control pattern 460 to fill a remaining portion of the second opening. Thus, a gate structure 480 including the gate insulation pattern 450, the work function control pattern 460 and the gate conductive pattern 470 may be formed.

The gate structure 480 together with the neighboring source/drain layer 390 in the first direction may constitute a transistor. Specifically, the transistor on the first region I of the substrate 300 may be a PMOS transistor, and the transistor on each of the second and third regions II and III of the substrate 300 may be an NMOS transistor.

As illustrated in FIG. 35, within a unit cell indicated with a broken-line, first and second pull-up transistors PU1 and PU2 may be formed on the first region I of the substrate, a first pull-down transistor PD1 and a first pass-gate transistor PG1 may be formed on the second region II of the substrate 300, and a second pass-gate transistor PG2 and a second pull-down transistor PD2 may be formed on the third region III of the substrate 300.

Contact plugs (not shown) and upper wirings (not shown) connected to the gate structure 480 and/or the source/drain layer 390 may be further formed to complete the fabrication of the semiconductor device.

As described above, in a method of manufacturing a semiconductor device in accordance with the inventive concept, when a process of replacing a dummy gate electrode with a gate electrode is performed, even if a distance between neighboring ones of the active fins is small, a portion of the dummy gate electrode may be well removed. Accordingly, a contact area between the gate electrode and the active fins may be maintained, and a threshold voltage distribution may not be high. The inventive concept, however, is not so limited. That is, the inventive concept may be applied to provide other effects, benefits and advantages readily apparent to those of ordinary skill in the art.

Furthermore, the inventive concept may be applied to various types of memory devices and systems including gate structures. For example, semiconductor devices according to the inventive concept may be employed by logic devices such as central processing units (CPUs), main processing units (MPUs), or application processors (APs), or the like. Additionally, the inventive concept may be applied to volatile memory devices such as DRAM devices or SRAM devices, or the like, or non-volatile memory devices such as flash memory devices, PRAM devices, MRAM devices, RRAM devices, or the like, which may include gate structures in peripheral circuit regions or cell regions.

Finally, although the present invention has been described with reference to a variety of examples thereof, those skilled in the art will readily appreciate that many modifications of the examples are possible without materially departing from the novel teachings and advantages of the present inventive concept as set forth in the appended claims.

What is claimed is:

1. A semiconductor device, comprising:
a substrate;
an isolation pattern defining active fins on the substrate, each of the active fins extending longitudinally in a first direction, and the active fins being spaced in a second direction crossing the first direction;
a gate electrode extending longitudinally in the second direction on the active fins and the isolation pattern; and
an isolation structure on a portion of the isolation pattern interposed between neighboring ones of the active fins in the second direction, the isolation structure including:
a first pattern of first material, the first pattern having a side surface and a bottom surface; and
a second pattern of second material different from the first material, the second pattern covering the bottom surface and a lower part of the side surface of the first pattern, and the second pattern having an upper surface adjacent a boundary between the lower part of the side surface of the first pattern and an upper part of the side surface of the first pattern so as to not to cover the upper part of the side surface of the first pattern.

2. The semiconductor device of claim 1, wherein the upper surface of the second pattern of the isolation structure is substantially coplanar with or situated at a level lower than that of upper surfaces of the active fins.

3. The semiconductor device of claim 1, wherein the second pattern of the isolation structure extends entirely around a lower portion of the first pattern of the isolation structure.

4. The semiconductor device of claim 1, wherein the first pattern of the isolation structure comprises silicon carbonitride (SiCN) or silicon oxycarbonitride (SiOCN), and the second pattern of the isolation structure comprises silicon nitride (SiNₓ) or silicon oxide (SiO₂).

5. The semiconductor device of claim 1, wherein the first pattern of the isolation structure comprises silicon nitride (SiNₓ), and the second pattern of the isolation structure comprises silicon oxide (SiO₂).

6. The semiconductor device of claim 1, further comprising:
a gate insulation pattern covering a lower surface and a side surface of the gate electrode.

7. The semiconductor device of claim 6, wherein the gate insulation pattern covers the upper part of the side surface of the first pattern of the isolation structure and the upper surface and a side surface of the second pattern of the isolation structure.

8. The semiconductor device of claim 6, wherein the gate insulation pattern has respective parts covering opposite side surfaces of the second pattern of the isolation structure, further comprising:
a dummy gate insulation pattern disposed on said portion of the isolation pattern as interposed between said portion of the isolation pattern and the isolation structure, between the neighboring ones of the active fins and between said respective parts of the gate insulation pattern.

9. The semiconductor device of claim 8, wherein the dummy gate insulation pattern comprises silicon and the gate insulation pattern is of material having a high dielectric constant greater than that of silicon oxide.

10. The semiconductor device of claim 1, wherein the first pattern of the isolation structure has an elliptical shape or a substantially circular shape in a plan view.

11. The semiconductor device of claim 1, wherein the first and second directions are substantially orthogonal to each other.

12. A semiconductor device, comprising:
a gate electrode extending longitudinally in a direction on a substrate; and
an insulating isolation structure extending through the gate electrode to separate the gate electrode into two parts in said direction, the insulating isolation structure including:
an upper portion; and
a lower portion having a width greater than a width of the upper portion as each taken in said direction, the lower portion including:
an inner portion of first material and integral with the upper portion; and
an outer portion of second material different from the first material and extending around the inner portion.

13. The semiconductor device of claim 12, wherein the inner portion of the lower portion of the insulating isolation structure is of material substantially the same as that of the upper portion of the insulating isolation structure, and the lower portion of the insulating isolation structure has a width in said direction equal to the width of the upper portion.

14. The semiconductor device of claim 13, wherein the upper portion of the insulating isolation structure and the inner portion of the lower portion of the insulating isolation structure each comprise silicon carbonitride (SiCN) or silicon oxycarbonitride (SiOCN), and the outer portion of the lower portion of the insulating isolation structure comprises silicon nitride (SiNₓ) or silicon oxide (SiO₂).

15. The semiconductor device of claim 12, wherein the outer portion of the lower portion of the insulating isolation structure covers a side surface and a bottom surface of the inner portion of the lower portion of the insulating isolation structure.

16. The semiconductor device of claim 12, further comprising:
a gate insulation pattern covering a bottom surface and a side surface of the gate electrode, a side surface of the upper portion of the insulating isolation structure, and an upper surface and a side surface of the outer portion of the lower portion of the insulating isolation structure.

17. The semiconductor device of claim 12, further comprising:
an isolation pattern defining active fins on the substrate,
wherein the gate electrode is disposed on the active fins and the isolation pattern, and
the insulating isolation structure is disposed on a portion of the isolation pattern interposed between neighboring ones of the active fins.

18. The semiconductor device of claim 17, wherein an upper surface of the lower portion of the insulating isolation structure is substantially coplanar with or situated at a level lower than that of upper surfaces of the active fins.

19. A semiconductor device, comprising:
a substrate;
an isolation pattern defining active fins on the substrate, each of the active fins extending longitudinally in a first direction, and the active fins being spaced in a second direction crossing the first direction;
a gate structure extending in the second direction on the active fins and the isolation pattern;
a gate spacer covering each of opposite side surfaces in the first direction of the gate structure; and
an isolation structure extending through the gate structure and including a second pattern and a first pattern stacked, the first and second patterns being of different materials from each other,
wherein the second pattern of the isolation structure is spaced from the gate spacer so as to not contact the gate spacer.

20. The semiconductor device of claim 19, wherein the gate structure includes a gate electrode, and a gate insulation pattern covering a lower surface and a side surface of the gate electrode, and
wherein the gate insulation pattern covers a side surface of the isolation structure and contacts the gate spacer.
